(19) United States
(12) Patent Application Publication
(10) Pub. No.: US 2020/0006041 A1
(43) Pub. Date: Jan. 2, 2020

(54) ELECTRODE UNIT HAVING AN INTERNAL ELECTRICAL NETWORK FOR SUPPLYING HIGH-FREQUENCY VOLTAGE, AND CARRIER ARRANGEMENT FOR A PLASMA TREATMENT SYSTEM

(71) Applicant: MEYER BURGER (GERMANY) GmbH, Hohenstein-Ernstthal (DE)

(72) Inventors: Hermann SCHLEMM, Milda (DE); Mirko KEHR, Amtsberg (DE); Erik ANSORGE, Chemnitz (DE)

(73) Assignee: MEYER BURGER (GERMANY) GmbH, Hohenstein-Ernstthal (DE)

(21) Appl. No.: 16/488,966

(22) PCT Filed: Jan. 25, 2018
(86) PCT No.: PCT/EP2018/051874

§ 371 Date: Aug. 27, 2019

(30) Foreign Application Priority Data
Feb. 28, 2017 (EP) 17158448.5

(51) Int. Cl. H01J 37/32

(52) U.S. Cl. CPC H01J 37/32577; H01J 37/32568; H01J 37/32091

(57) ABSTRACT

The invention relates to an electrode unit comprising a plurality of plasma electrode pairs, which, at a specific applied voltage, are suitable for igniting a plasma between a first plasma electrode and a second plasma electrode of each plasma electrode pair; at least one internal electrical supply network that is suitable for supplying a first voltage to all the first plasma electrodes and to supply a second voltage to all the second plasma electrodes, at least one of the voltages being high frequency; and a first and a second connection terminal suitable for feeding the first voltage and the second voltage into the at least one supply network. The internal electrical supply network contains a plurality of lines, wherein by way of the arrangement, the geometric dimensions and/or the material of the lines, and/or the arrangement of a feed point of the first or second voltage within the supply network, the supply network is adapted to the electrode unit and the frequency of the first and/or the second voltage.

The invention relates to an electrode unit for a plasma treatment system, wherein the electrode unit includes a plurality of plasma electrode pairs adapted to generate a capacitively coupled plasma, in particular in vacuo, and a different electrical high-frequency voltage is supplied to the two plasma electrodes of each plasma electrode pair in each case via an internal electrical supply network. Furthermore, the invention also relates to a carrier arrangement for a plasma treatment system, wherein the carrier arrangement contains at least two such electrode units.

Plasma processes are used, for example, in the production of solar cells, in microelectronics or in the finishing of substrate surfaces (e.g. glass) for deposition or removal of layers or particles, for doping of layers, for example by plasma immersion ion implantation, or for cleaning or activating the surface of a substrate. In the following, all these plasma processes are referred to as plasma treatment.

In capacitively coupled plasmas, the substrate to be treated is located in a space between two plasma electrodes, wherein a low or high-frequency voltage is applied to these two plasma electrodes. The substrate is usually acted upon with a voltage by a direct ohmic contact with one of the plasma electrodes. However, in particular with plasma-assisted deposition of dielectric layers, corresponding insulating layers can also form on the plasma electrode at least in a substrate edge region, which layers negatively influence the homogeneity of the deposition on other substrates subsequently deposited on the same plasma electrode.

In order to increase the throughput of substrates in the plasma treatment, batch systems in which several substrates are treated simultaneously are used. In this case, the substrates may be arranged side by side or one above the other with the surface to be processed. The substrates are in each case arranged between the plasma electrodes of a plasma electrode pair, wherein the plasma electrodes are electrically insulated from each other and connected to a voltage feed such that a plasma can be generated capacitively between the plasma electrodes of each of these plasma electrode pairs. In the case of substrates arranged one above the other, up to 200 plasma electrodes arranged in parallel at a typical distance from each other of 3 mm to 30 mm are electrically interconnected in a plasma electrode unit such that every second plasma electrode has a common electrical connection. An AC voltage which is sufficiently large to ignite a plasma between all the plasma electrodes is then applied to the resulting arrangement of two electrode groups having two terminals. Preferably, for this purpose a symmetrical voltage is applied with respect to the ground (vacuum chamber and other components) surrounding the plasma electrodes, i.e. when a positive voltage +U/2 is applied to the one electrode group, then −U/2 is applied to the other electrode group. Therefore, the voltage U is applied only between the plasma electrodes, which voltage is large enough to generate the plasma between the plasma electrodes. No plasma is generated to the surrounding ground parts, because the voltage applied here and being U/2 is too small for plasma generation. This type of plasma generation (symmetrical generator coupling) is particularly advantageous in plasma processes with many substrates on many plasma electrodes, because the insulation of live parts to avoid parasitic plasmas can be almost completely eliminated.

Such an electrode unit is described, for example, in EP 0 143 479 A1. In this case, the individual electrode plates are held at a defined distance from each other by electrically insulating spacers and are each contacted with an electrical conductor arranged on a carrier. The electrode unit thus contains two carriers, each with an electrical conductor, wherein the carriers extend in each case over the entire length of the electrode unit, i.e. from the first electrode plate to the last electrode plate.

DE 10 2015 004 352 A1 also describes a similar electrode unit, wherein each plate-shaped and electrically conductive substrate support is arranged in a respective plane and provided with a contact nose. A contact block made of an electrically highly conductive material, in particular graphite, is arranged between two electrically identically connected substrate supports, the contact block ensures the electrical connection between the individual substrate supports and thus the supply of the voltage across all the identically connected substrate supports while simultaneously maintaining a predetermined distance from each other.

Typically, solid graphite rods or contact pieces made of graphite with a cross section of (20×5) mm² are used for supplying the voltage to identically connected plasma electrodes.

This type of voltage feed is well suited for supplying a low-frequency voltage having a frequency ranging from 10 Hz to 1000 kHz uniformly to all the identically connected plasma electrodes. The same voltage is thus applied to each identically connected plasma electrode, so that a homogeneous plasma can be generated in all the plasma electrode pairs of the electrode unit.

While the above-mentioned symmetrical plasma wiring for low-frequency voltages of 10 Hz to 1000 kHz is prior art and is widely used, it is problematic for high-frequency plasmas with frequencies of 1 MHz to 100 MHz.

Plasma processes with voltages at higher frequencies, for example 13.56 MHz or 40 MHz, have particular advantages, such as a good homogeneity of the substrate treatment even with thick parasitic dielectric layers on the plasma electrodes in the substrate edge region and a gentle substrate treatment by a low energy of the ions striking the substrate from the plasma. Such high-frequency plasmas and the associated plasma processes (such as plasma enhanced chemical vapour deposition (PECVD) or reactive ion etching (RIE)) have completely displaced low-frequency plasma processes in the semiconductor industry due to their process advantages mentioned above. They are normally used in single-disc reactors, i.e. a single substrate, such as a silicon wafer with a diameter of 300 mm, is processed in a single electrode arrangement of two plasma electrodes. The HF generator coupling takes place asymmetrically, i.e. the substrate lies on the ground electrode and a second electrode connected to the high-frequency voltage acts as a counter-electrode that is built well-insulated against ground outside of the electrode gap to prevent further parasitic plasmas there.

For voltages in this frequency range and/or electrode units having a very large number of identically connected plasma electrodes, for example 20 or more plasma electrodes, the generation of a symmetrical high-frequency plasma is problematic. In particular, the voltage distribution achieved across the electrode unit is no longer sufficiently homogeneous.

In order to solve this problem, various possibilities are known from the prior art. Thus, U.S. Pat. No. 5,733,511 A describes an arrangement in which each identically connected plasma electrode, in the present case arranged side by side, is individually fed a voltage from outside via a separate coaxial cable with a length of (2N+1)λ/4 (with N=0, 1, 2 . . . ) from a high-frequency voltage generator, hereinafter referred to as an HF generator, and the associated matching network (matching network, match network or match box). For a large number of identically connected plasma electrodes this is very complex, for example due to the separate vacuum feedthrough of the voltage feed in a treatment chamber of the plasma treatment system.

In U.S. Pat. No. 4,887,005 A, an electrode unit is described in which each identically connected plasma electrode is supplied with power via an individually adjustable inductance or capacitance in a separate supply line from the HF generator and the matching network, which however is also very complex, or which has a differential drive transformer and a centre-tapped coil, wherein in each case one end of the output winding of the transformer or each end of the coil is connected to a specific, simple one of the identically connected plasma electrodes. By use of additional coils, the power can also be further divided so that in each case 2ⁿ (with n=1, 2, 3 . . . ) plasma electrodes can be supplied with a same power. However, at the two ends of the centre-tapped coil or of the transformer, in each case half the output voltage of opposite sign is applied. The output voltage of the HF generator must be selected to be very high for a large number of identically connected plasma electrodes, which leads to problems in the implementation. In addition, here too, all the additional components such as inductors, capacitors, transformers and centre-tapped coils are arranged outside the treatment chamber and thus outside the electrode unit, leading to a large number of vacuum voltage feedthroughs.

It is therefore an object of the invention to provide an electrode unit in which nearly the same high-frequency voltage is fed to all the identically connected plasma electrodes, wherein the disadvantages of the prior art are avoided or reduced. Moreover, it is an object to provide a carrier arrangement for plasma treatment of a large number of substrates in which at least two such electrode units are advantageously arranged.

The object is achieved by an electrode unit according to claim 1 and by a carrier arrangement according to claim 16. Preferred embodiments can be found in the dependent claims.

An electrode unit suitable for plasma treatment of a plurality of substrates in a treatment chamber of a plasma treatment system has a plurality of plasma electrode pairs arranged along a first direction. Each plasma electrode pair consists of a first and a second plasma electrode arranged parallel to each other and opposite each other and electrically insulated from each other. Preferably, the first and second plasma electrodes of the electrode unit are arranged alternately along the first direction. Each plasma electrode pair is suited to ignite a plasma in a plasma space between the first and second plasma electrodes when a defined voltage is present between the first and second plasma electrodes. The electrode unit further has at least one internal electrical supply network capable of feeding, within the treatment chamber, a first voltage to each first plasma electrode of the electrode unit and a second voltage different from the first voltage to each second plasma electrode of the electrode unit, wherein at least one of the first and the second voltage is a high-frequency voltage and has a frequency in the range between 1 MHz and 100 MHz. Preferably, both the first voltage and the second voltage are high-frequency voltages. The at least one internal electrical supply network, together with the plasma electrodes, the plasmas generated between the plasma electrodes, and the substrates, forms an internal electrical network of the electrode unit during operation, i.e. given application of an electrical voltage sufficient to ignite and maintain the plasmas, wherein the internal electrical network is inherent in the electrode unit and can be controlled from outside only through the supplied voltages.

To feed the first and the second voltage to the at least one internal electrical supply network, the electrode unit further has a first connection terminal and a second connection terminal. The first connection terminal is adapted to feed the first voltage to the at least one internal electrical supply network, and the second connection terminal is adapted to feed the second voltage to the at least one internal electrical supply network. A high-frequency power provided by at least one generator arranged outside the treatment chamber can be transmitted via ohmic contacts to the first and the second connection terminal. Alternatively, a coupling arrangement can also be used that generates the abovementioned voltages to the connection terminals contactlessly by capacitive or inductive transmission of a high-frequency power provided by a generator.

The first and the second voltages differ in at least one of the following features: effective value, frequency or phase. Preferably, the first and the second voltage are generated symmetrically with respect to ground, i.e. they differ not in frequency and effective value but by a phase position differing by 180°. However, an asymmetrical voltage feed is also possible, for example by the first or the second voltage being a high-frequency voltage while the other voltage is equal to zero and corresponds to ground. In any event, the electrode voltage resulting from the difference in the electrical potentials of the plasma electrodes of a plasma electrode pair during operation is a high-frequency voltage with a defined frequency in the range of 1 MHz to 100 MHz.

The at least one internal electrical supply network of the electrode unit according to the invention is designed according to the arrangement of the plasma electrodes in the electrode unit, in particular the number and spacing of the plasma electrodes from each other, and according to the frequency of the first voltage and/or the second voltage, wherein in particular it is adapted to the frequency of the electrode voltage. In other words, the at least one internal electrical supply network is designed such that the electrode unit is adapted for operation with a concrete first voltage and a concrete second voltage. During operation, the at least one internal electrical supply network together with at least one external matching network is set to resonance and matching of the internal electrical network of the electrode unit and a homogeneous voltage distribution inside the electrode unit. The at least one external matching network is arranged between a voltage generator disposed outside the treatment chamber and at least one of the first or second connection terminals. By means of the concrete design of the at least one internal electrical supply network, almost the same voltage is present between the first and the second plasma electrode of each plasma electrode pair during operation and a virtually identical plasma power density is generated on each substrate. This is particularly advantageous when there are more than ten plasma electrode pairs in an electrode unit.

The at least one internal electrical supply network has supply lines between the first and the second connection terminal and at least two first and at least two second plasma electrodes and/or intermediate lines between two adjacent first or second plasma electrodes, respectively, and in each case a feed point to a first or second system of interconnected intermediate lines and in each case a connecting line between the first and the second connection terminal and the associated feed point. The concrete design of the supply network consists of a suitable arrangement of the supply lines and/or suitable geometric dimensions of the supply lines and/or of the intermediate lines and/or of the connecting lines and/or a suitable material of the supply lines and/or of the intermediate lines and/or of the connecting lines and/or a suitable arrangement of the feed point with respect to the electrode unit along the first direction. All the supply lines and/or intermediate lines and/or connecting lines are real electrical lines, i.e. having a defined parasitic inductance or parasitic capacitance, the influence of which on the internal electrical network of the electrode unit given application of a high-frequency voltage with a frequency in the range between 1 MHz and 100 MHz is not negligible.

The parasitic line inductances or line capacitances can be influenced, for example, by the suitable choice of the geometric dimensions and/or the material of the supply lines and/or of the intermediate lines and/or of the connecting lines.

All the designs mentioned of the at least one internal electrical supply network are explained below with reference to the drawings.

The nature of the concrete design of the at least one supply network, for example concrete materials and concrete dimensions of the lines in the supply network or the concrete arrangement of a feed point in the supply network, can be evaluated with the aid of computer modelling or simulations and selected corresponding to an arrangement of plasma electrodes in the electrode unit.

With more than 50 plasma electrode pairs in an electrode unit, however, the effort of the concrete design of the internal electrical supply network is very high. Therefore, the carrier arrangement according to the invention for plasma treatment of a large number of substrates in a plasma treatment chamber has at least two of the above-described electrode units according to the invention. Preferably, each electrode unit contains between 20 and 30 plasma electrode pairs, particularly preferably 25 plasma electrode pairs.

In the following, the invention and its various embodiments will be explained with reference to the embodiments and the drawings, in which:

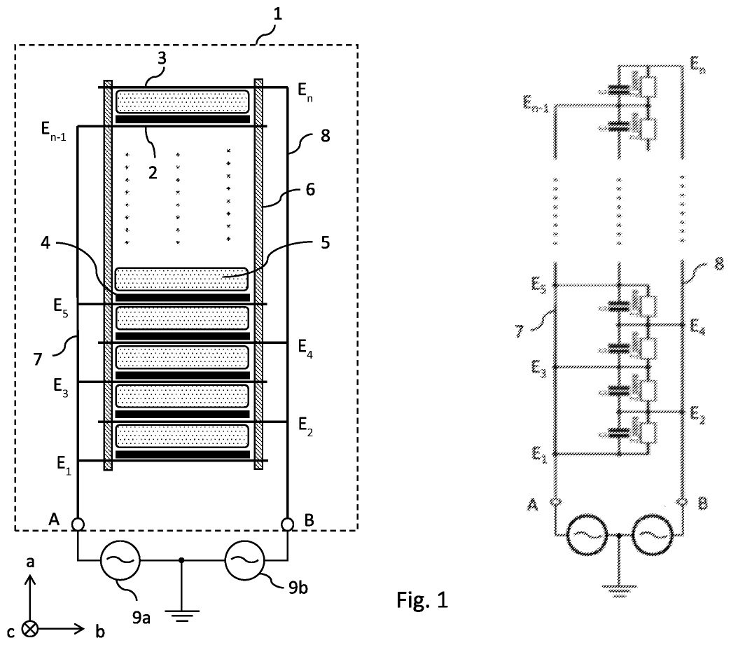

FIG. 1 is a schematic view of an electrode unit according to the prior art and an electrical equivalent circuit diagram of the internal electrical network of said electrode unit for a low-frequency voltage supply;

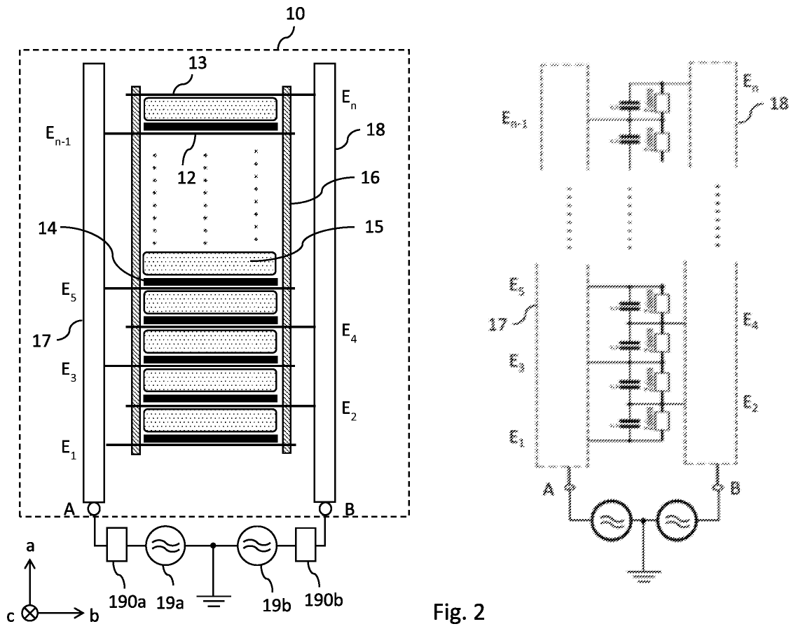

FIG. 2 is a schematic view of an electrode unit according to the invention and an electrical equivalent circuit diagram of the internal electrical network of said electrode unit for a high-frequency voltage supply;

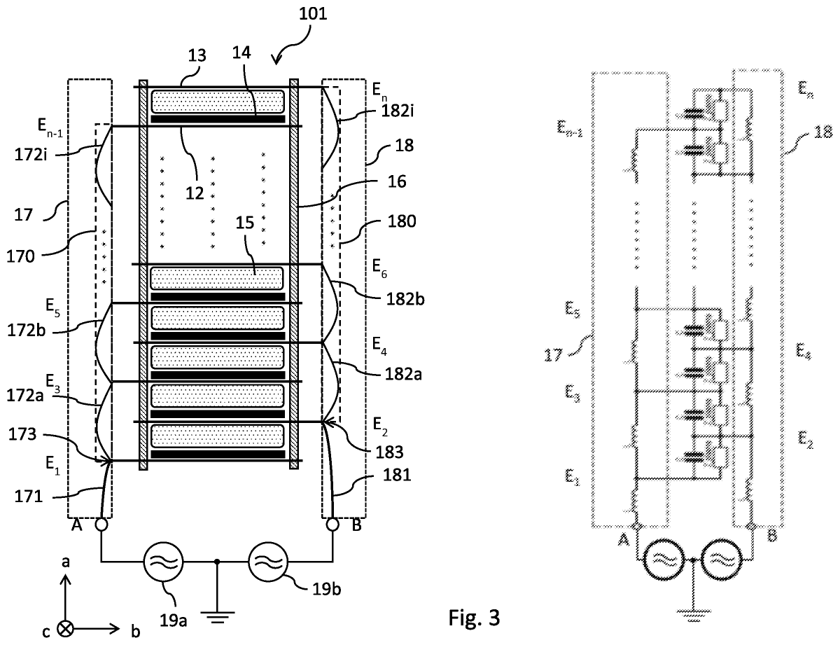

FIG. 3 is a schematic view of a first embodiment of the electrode unit according to the invention having two supply networks with row-shaped wiring of the plasma electrodes and a codirectional coupling of the supply networks, and an electrical equivalent circuit diagram of the resulting internal electrical network;

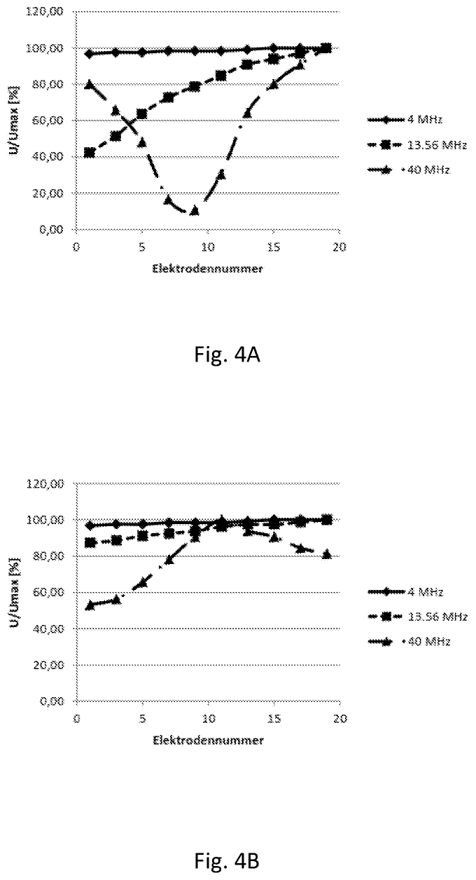

FIG. 4A shows the distribution of a high-frequency voltage through 10 identically connected plasma electrodes for an electrode unit according to the prior art with codirectional coupling;

FIG. 4B shows the distribution of a high-frequency voltage through 10 identically connected plasma electrodes for the first embodiment of the electrode unit according to the invention;

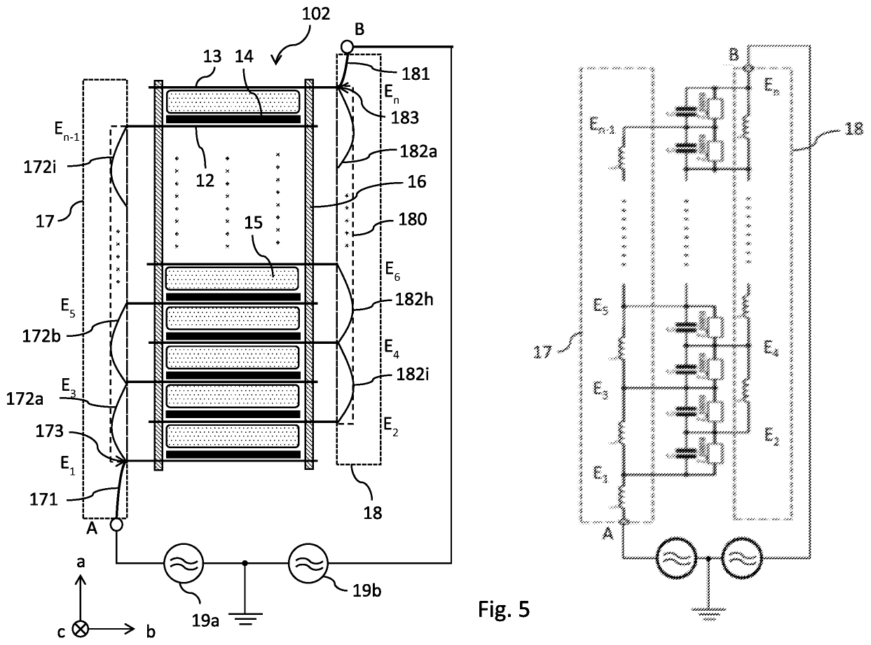

FIG. 5 is a schematic view of a second embodiment of the electrode unit according to the invention having two supply networks with row-shaped wiring of the plasma electrodes and a reverse coupling of the supply networks, and an electrical equivalent circuit diagram of the resulting internal electrical network;

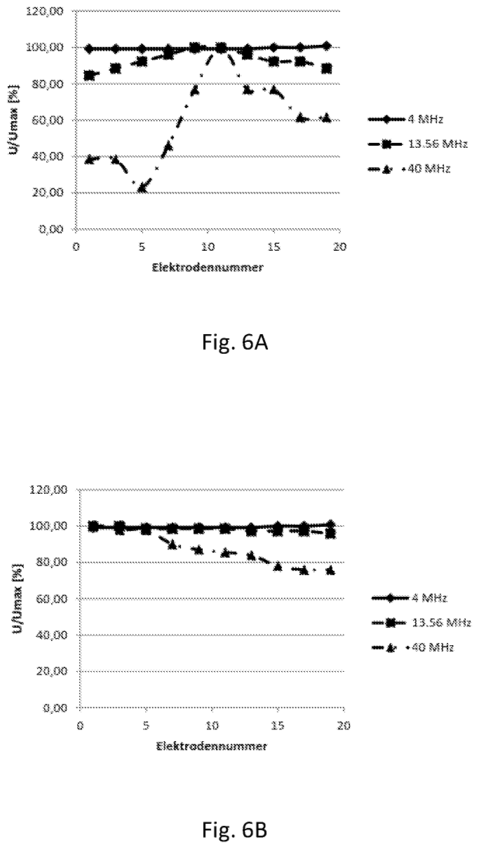

FIG. 6A shows the distribution of a high-frequency voltage through 10 identically connected plasma electrodes for an electrode unit according to the prior art with reverse coupling;

FIG. 6B shows the distribution of a high-frequency voltage through 10 identically connected plasma electrodes for the second embodiment of the electrode unit according to the invention;

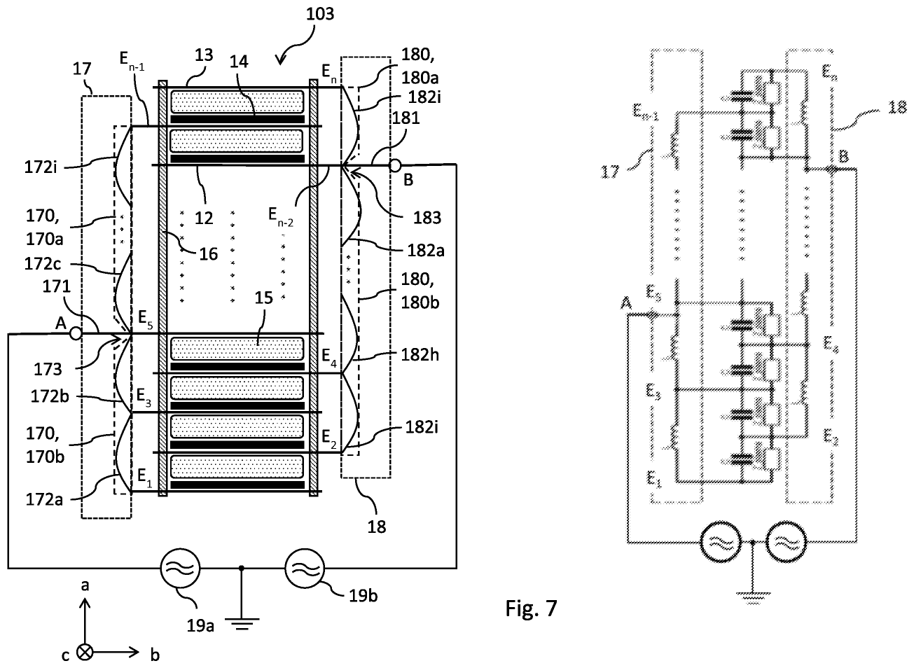

FIG. 7 is a schematic view of a third embodiment of the electrode unit according to the invention having two supply networks with row-shaped wiring of the plasma electrodes and arbitrarily arranged feed points, and an electrical equivalent circuit diagram of the resulting internal electrical network;

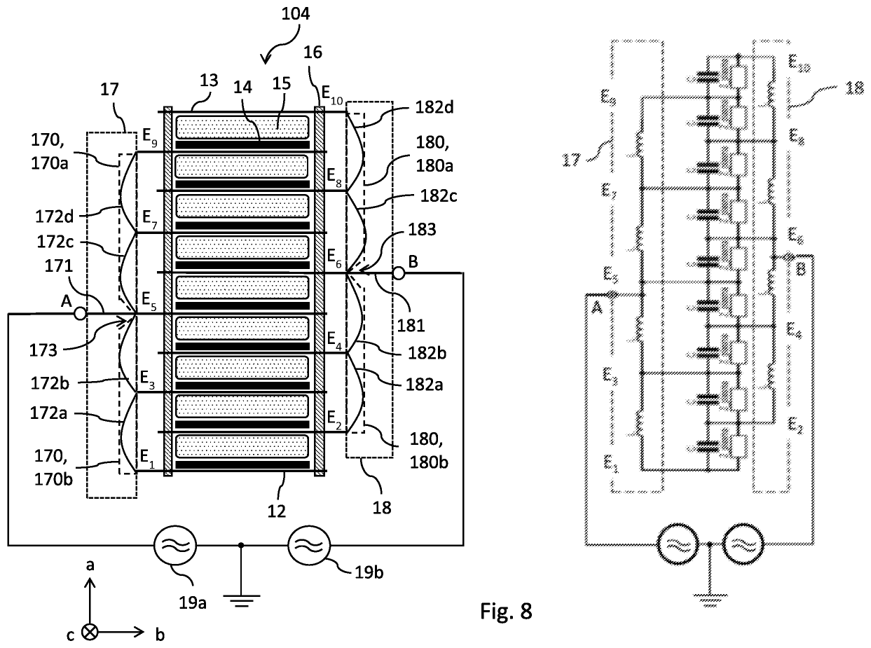

FIG. 8 is a schematic view of a fourth embodiment of the electrode unit according to the invention having two supply networks with row-shaped wiring of the plasma electrodes and centrally arranged feed points, and an electrical equivalent circuit diagram of the resulting internal electrical network;

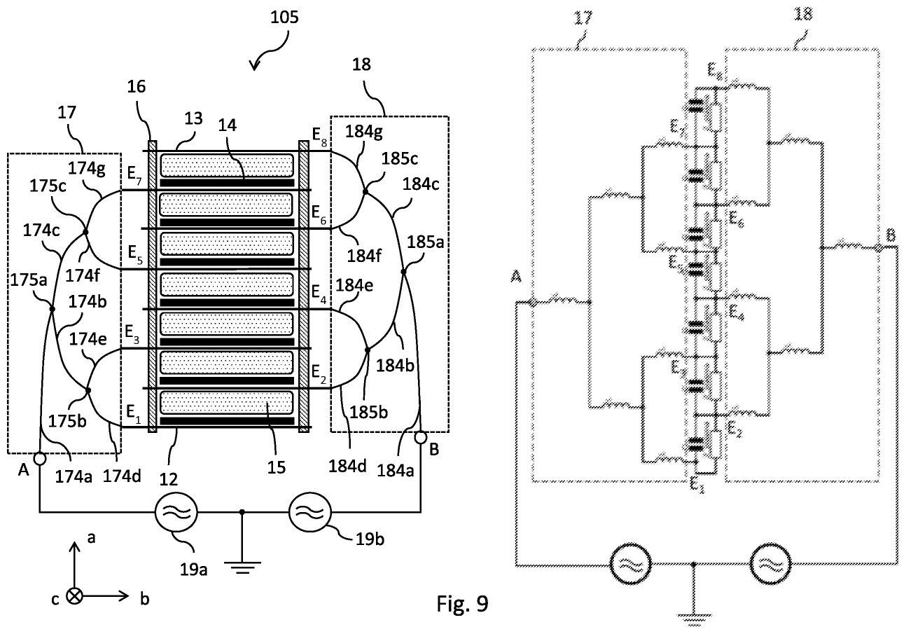

FIG. 9 is a schematic view of a fifth embodiment of the electrode unit according to the invention having two supply networks with tree-shaped wiring of the plasma electrodes, and an electrical equivalent circuit diagram of the resulting internal electrical network;

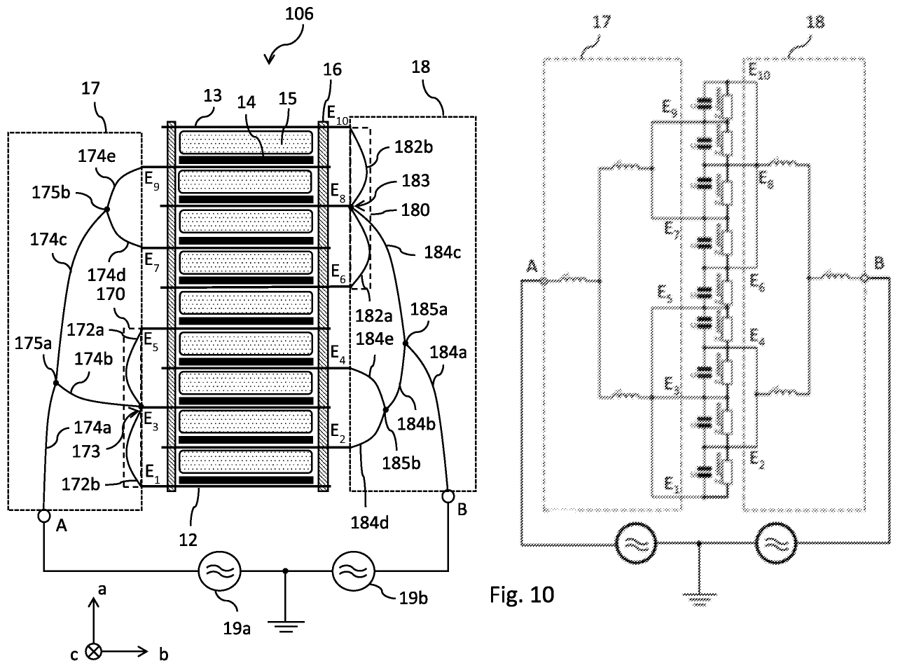

FIG. 10 is a schematic view of a sixth embodiment of the electrode unit according to the invention having two supply networks with row-shaped and tree-shaped wiring of the plasma electrodes, and an electrical equivalent circuit diagram of the resulting internal electrical network;

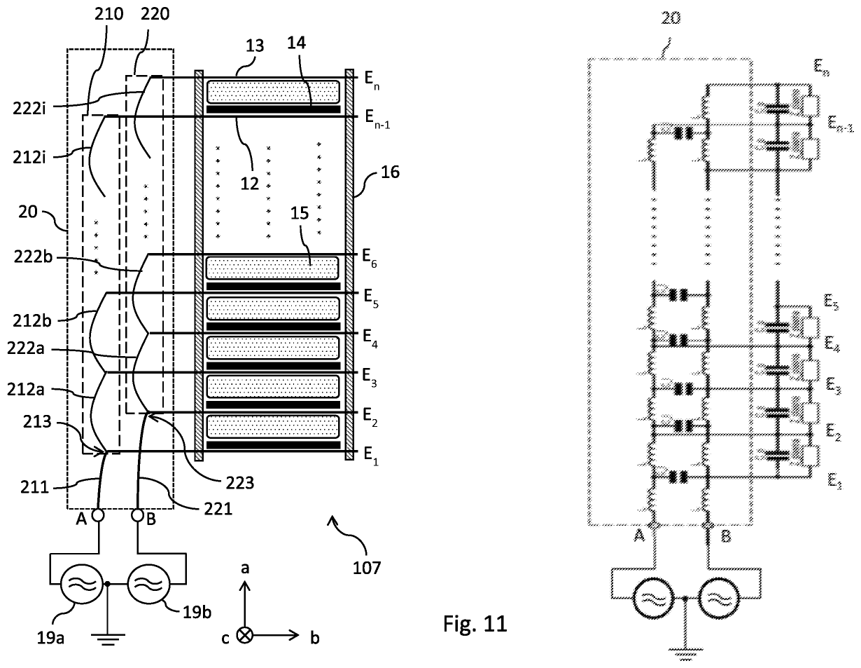

FIG. 11 is a schematic view of a seventh embodiment of the electrode unit according to the invention having a supply network formed as a high-frequency line, wherein the first and the second connection terminals lie at the same end of the high-frequency line, and an electrical equivalent circuit diagram of the resulting internal electrical network;

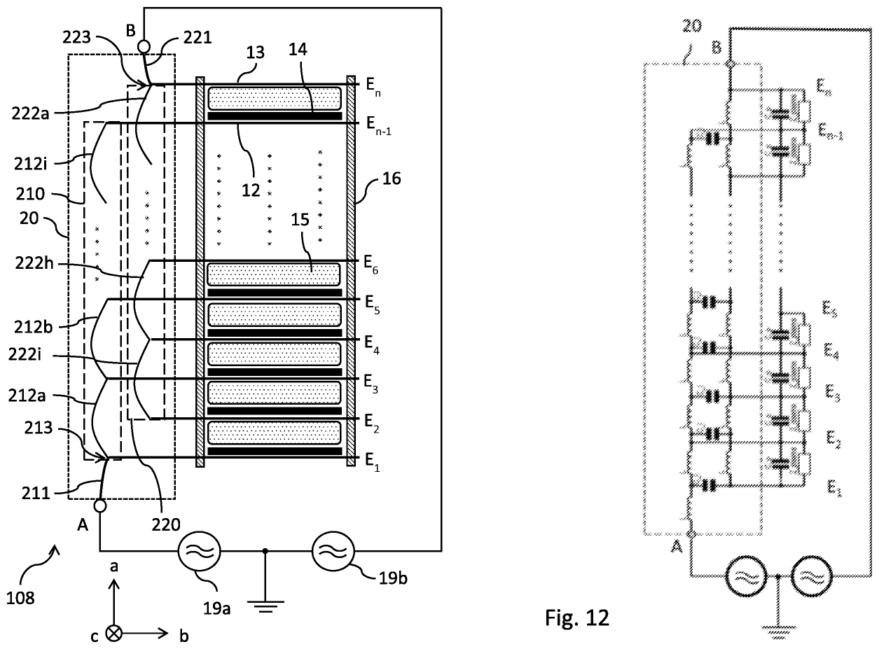

FIG. 12 is a schematic view of an eighth embodiment of the electrode unit according to the invention having a supply network formed as a high-frequency line, wherein the first and the second connection terminals lie at opposite ends of the high-frequency line, and an electrical equivalent circuit diagram of the resulting internal electrical network;

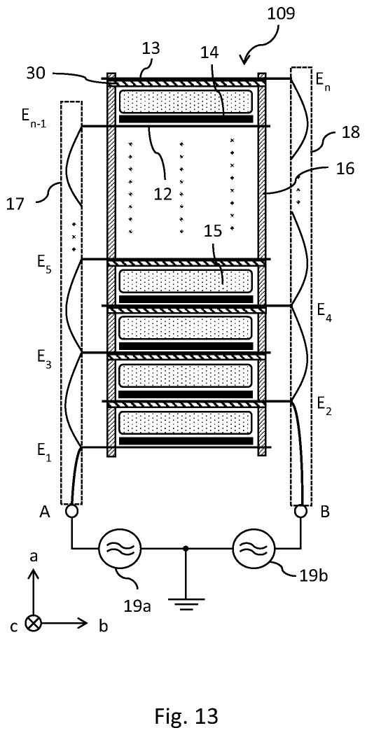

FIG. 13 is a schematic view of a ninth embodiment of the electrode unit according to the invention having two supply networks and a dielectric layer on a plasma electrode;

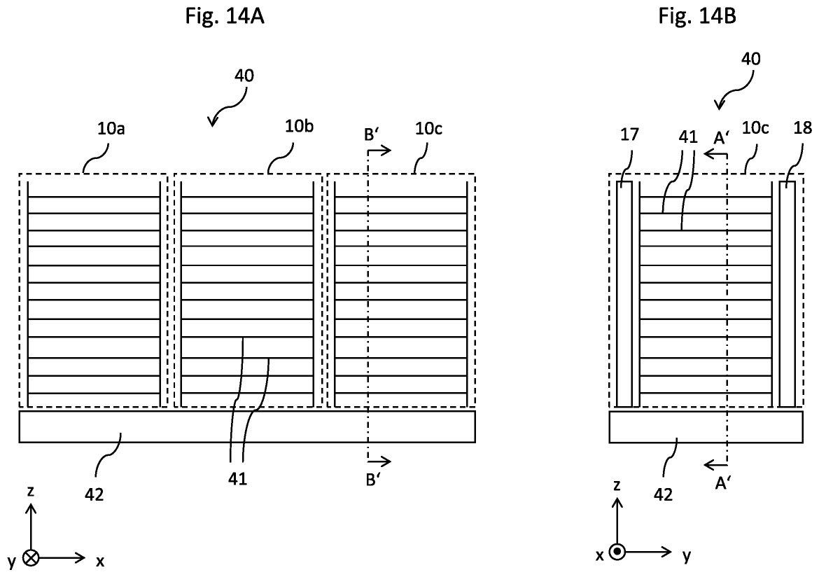

FIG. 14A is a schematic view of a first embodiment of a carrier arrangement according to the invention with electrode units according to the invention in a first cross-sectional plane;

FIG. 14B is a schematic view of the first embodiment of a carrier arrangement in a second cross-sectional plane perpendicular to the first cross-sectional plane;

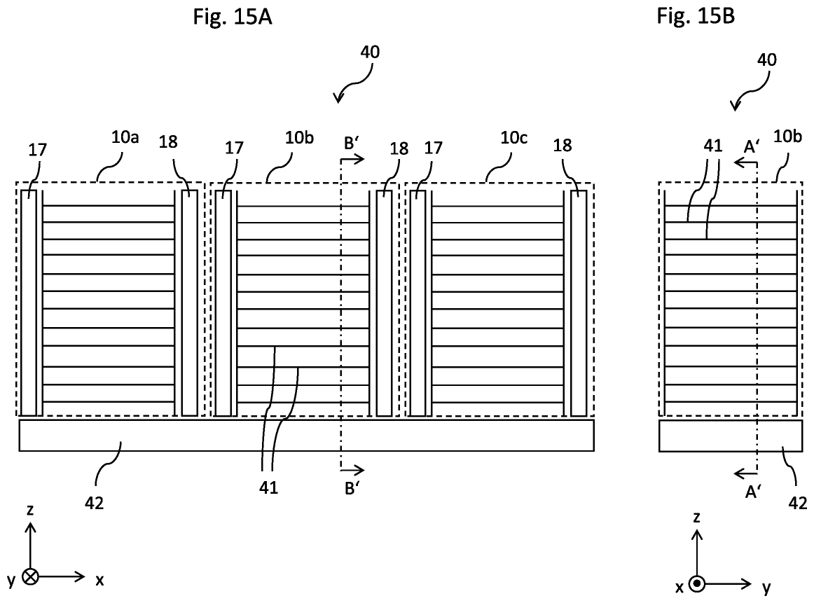

FIG. 15A is a schematic view of a second embodiment of a carrier arrangement according to the invention with electrode units according to the invention in a first cross-sectional plane; and

FIG. 15B is a schematic view of the second embodiment of a carrier arrangement in a second cross-sectional plane perpendicular to the first cross-sectional plane.

FIG. 1 shows an electrode unit 1 according to the prior art that is suitable for plasma treatment of a plurality of substrates 4 in a treatment chamber of a plasma treatment system. The electrode unit 1 can be fixedly mounted in the treatment chamber or moved as a whole into and out of it.

Moreover, there is also the possibility that the electrode unit 1 is moved in the chamber in a straight, rotating or otherwise uniform or non-uniform manner during the plasma treatment. The substrates 4 are not part of the electrode unit 1.

The electrode unit 1 has a large number of plasma electrode pairs arranged along a first direction (a-axis). Each plasma electrode pair consists of a first plasma electrode 2 and a second plasma electrode 3, arranged parallel to each other and opposite each other and electrically insulated from each other. Preferably, the first and the second plasma electrode 2, 3 are arranged alternating along the first direction and extend with a surface area, on which a substrate 4 rests during a plasma treatment, perpendicular to the first direction, i.e. in a plane parallel to a plane spanned by the two other directions (b and c-axes) of a three-dimensional Cartesian coordinate system to which the first direction also belongs. However, the surfaces of the first plasma electrodes 2 and the second plasma electrodes 3 can also extend in a plane spanned by the first direction and a further direction, so that the respective plasma electrodes are arranged side by side along the first direction. The plasma electrodes of a plasma electrode pair then lie opposite one other along one of the other two directions of the Cartesian coordinate system. The first and the second plasma electrodes 2, 3 are made of an electrically conductive material, such as graphite or aluminium, so that a plasma is ignited in a plasma space 5 upon application of a defined voltage between the first and second plasma electrode 2, 3 of a plasma electrode pair.

The surface area of the plasma electrodes 2, 3 is typically slightly larger than the surface area of the substrates 4 to be treated, wherein the outer shape (outline, contour) of the surface area of the plasma electrodes 2, 3 approximately corresponds to that of the substrates 4. However, for electrically well-conductive substrates 4, only part of the substrate 4 may be in contact with the respective plasma electrode, wherein this plasma electrode can then have an arbitrary shape. For example, a plasma electrode 2, 3 has an area of (200×200) mm² at a size of the substrate 4 of (156×156) mm². The distance between the first plasma electrode 2 and the second plasma electrode 3 of a plasma electrode pair is in the range between 3 mm and 50 mm.

The electrode unit 1 has n plasma electrodes 2, 3, where n is usually an even number between 10 and 200. In this case, there are n/2 first plasma electrodes 2 (labelled in the drawing E₁, E₃, E₅, . . . , Eₙ₋₁) and n/2 second plasma electrodes 3 (labelled in the drawing E₂, E₄, . . . , Eₙ). However, there can also be an odd number of plasma electrodes 2, 3 present. The individual plasma electrodes 2, 3 are spaced apart from each other along the first direction by insulating supports 6 and are supported by them. The supports 6 may have different shapes and can be, for example, a plurality of rod-shaped supports, each extending along the first direction, or be formed as a housing in which the plasma electrodes are arranged and having openings for introducing the substrates 4 on at least one side.

All the first plasma electrodes 2, i.e. E₁ to Eₙ₋₁, are connected via a common first distribution line 7 to a first connection terminal A, while all the second plasma electrodes 3, i.e. E₂ to Eₙ, are connected via a common second distribution line 8 to a second connection terminal B. Two generators 9a and 9b, which generate two voltages of the same frequency and amplitude but having a different phase position (e.g. 180° phase offset) relative to ground, are connected to the connection terminals A and B. Instead of the two generators, coupling arrangements can also be employed that transmit a power to the electrode arrangement contactlessly by inductive or capacitive means and deliver two voltages phase-shifted by 180° with respect to ground from their respective electrical coupling network to the terminals A and B, which are further connected to the distribution lines 7, 8.

According to the prior art, the first and the second distribution lines 7, 8 are usually designed as solid graphite rods or plates or contact pieces made of graphite having a cross section (in the b-c plane) of, for example, (20×5) mm². The length of the distribution lines 7, 8 along the first direction (a-axis) results from the number of plasma electrodes 2, 3 or the distance between connection terminals A and B and the last plasma electrodes 2 and 3, which are supplied with voltage via the respective distribution lines 7 and 8, respectively.

For low-frequency voltages applied to the plasma electrodes 2, 3, i.e. for voltages with a frequency in the range of 10 Hz to 1000 kHz, the distribution lines 7 and 8 act as ideal conductors, the parasitic inductances and parasitic capacitances of which can be ignored. Therefore, all the first plasma electrodes 2 and all the second plasma electrodes 3 can be considered as parallel-connected and have the same voltage. The internal electrical network of electrode unit 1 can thus be characterised by the electrical equivalent circuit diagram shown on the right in FIG. 1, wherein the plasma ignited between the plasma electrodes of a plasma electrode pair is shown in each case as plasma impedance Z_plasma, and the plate capacitor formed by the plasma electrodes of the plasma electrode pair in each case is shown as capacitance C. Ignoring system-related inhomogeneities, all the plasmas ignited in the electrode unit 1 therefore have the same plasma parameters so that all the substrates 4 can be processed homogeneously.

However, for plasma processes with voltages having higher frequencies, such as 13.56 MHz or 40 MHz, and/or electrode units with a very high number of identically connected plasma electrodes, for example 10 or more plasma electrodes, the voltage distribution thus reached is no longer sufficiently homogeneous. This is explained in more detail later with reference to FIG. 4A and 6A.

FIG. 2 now shows an electrode unit 10 according to the invention which contains the first plasma electrodes 12, second plasma electrodes 13, substrates 14, plasma spaces 15, insulating supports 16 and connection terminals A and B, and in this regard said electrode unit has no differences from the electrode unit 1 of FIG. 1. However, the electrode unit 10 is suitable for a plasma treatment of the substrates 14, in which the plasma is ignited with the aid of two high-frequency voltages provided by two high-frequency voltage generators 19a and 19b with respect to ground. Preferably, the two voltages are the same but phase-shifted, preferably by 180°. The frequency of these voltages is in the range between 1 MHz and 100 MHz, preferably in the range between 10 MHz and 40 MHz, for example 13.56 MHz. The voltages are transmitted from the high-frequency voltage generators 19a, 19b in each case via an associated external matching network 190a, 190b to the first connection terminal A and the second connection terminal B. The external matching networks, which are not part of the electrode unit 10, for reasons of clarity are not shown in FIGS. 3, 5 and 7 to 13, but they are present there in the same way.

To achieve a homogeneous plasma ignition over all the plasma electrode pairs of electrode unit 10 during operation, the electrode unit 10 has at least one internal electrical supply network that feeds a first voltage provided by the generator 19a and the external matching network 190a to all the first plasma electrodes 12, and a second voltage provided by the generator 19b and the external matching network 190b to all the second plasma electrodes 13. FIG. 2 shows an embodiment with two internal electrical supply networks 17, 18. Embodiments with only one internal electrical supply network 20 are explained further with reference to FIGS. 11 and 12. Each supply network 17, 18 or 20 integrated into the electrode unit 10 consists of real lines provided with parasitic inductances and, if so, also parasitic capacitances, the dimensions, materials, arrangements and internal connections of which lines are designed such that, during operation, almost the same high-frequency electrode voltage is present between the plasma electrodes 12, 13 of each plasma electrode pair. “Almost” means that even with very good matching of the networks slight voltage differences can exist, but, in the sense of plasma treatment of the substrates 14, they are tolerable or can be reduced to a tolerable degree by further measures, such as further inserted capacitances or inductances, as described by way of example with reference to FIG. 13. During operation, the external matching networks 190a and 190b are set such that resonance occurs between the internal electrical network of the electrode unit 10 and the external matching networks 190a, 190b and all the networks are matched to each other.

Which voltage differences are tolerable for a concrete plasma treatment of substrates depends on the requirements imposed on the homogeneity of the plasma treatment over the plurality of substrates. This means: Which voltage differences are still tolerable essentially depends on the homogeneity goals specified by a user of the plasma treatment system for a concrete plasma treatment process. In solar cell production, for example, it is generally assumed that a deviation of 10% or less between the electrode voltages within the electrode unit is tolerable.

For this purpose, the lines present in the at least one internal electrical supply network, i.e. supply lines and/or intermediate lines and/or connecting lines, are no longer formed as a solid structure of graphite as in the prior art but instead, for example, are formed as metal strips with a thickness in the range of 0.1 mm to 5 mm, preferably in the range of 0.2 mm to 0.5 mm, and a width in the range of 1 mm to 100 mm, preferably 20 mm to 60 mm. The thickness and the width characterise the cross-sectional area of the line, while the length of the line is measured along the direction of current flow. The length of the metal strips used in one network can vary and depends on the type of line.

The metal strips preferably are made of a highly conductive material such as aluminium, copper, silver or silver-plated copper (copper with a silver layer on the surface). The selection of the material depends not just on the electrical conditions in the internal electrical network of the electrode unit during operation, but also on the chemical properties of said materials with respect to the substances, molecules, radicals, etc. present in the treatment chamber, and in particular in the plasma.

For example, the metal strips are made of copper and each have a thickness of 0.25 mm and a width of 30 mm.

If the metal strips are made of aluminium, they have a thickness of 0.5 mm and a width of 50 mm.

In the embodiment shown in FIG. 2, the first voltage is fed to a first supply network 17 from connection terminal A and is made available to each first plasma electrode 12 by the first supply network 17, while the second voltage is fed to a second supply network 18 from connection terminal B and is made available to each second plasma electrode 13 by the second supply network 18.

With reference to the following drawings, embodiments of the electrode unit 10 according to the invention with two internal electrical supply networks 17, 18 should be presented, wherein the two supply networks 17, 18 are each spatially and electrically separated from each other. This means that the distance of the two supply networks 17, 18 from each other is large enough that a capacitive and inductive coupling between the lines of the two supply networks 17, 18 is negligible. This distance is preferably in the range of 100 mm to 500 mm, for example 200 mm. The spatial and electrical separation can be implemented, for example, by an arrangement of the two supply networks 17, 18 on different sides of electrode unit 10 with respect to a direction which is perpendicular to the first direction. For example, the two supply networks 17, 18 are arranged on opposite sides of the electrode unit 10 with respect to the b-axis, as shown in FIG. 2.

FIG. 3 shows a first embodiment 101 of the electrode unit having two internal electrical supply networks 17, 18. The first voltage is fed in the first supply network 17 from the first connection terminal A via a first connecting line 171 into a first system 170 of interconnected first intermediate lines 172a-172i. The intermediate line 172a connects the first plasma electrode 12 (E₁) first arranged in the first direction with the first plasma electrode 12 (E₃) arranged as the next one along the first direction, the intermediate line 172b connects this first plasma electrode 12 (E₃) with the next first plasma electrode 12 (E₅) arranged along the first direction, and so forth until ultimately the last first plasma electrode 12 (Eₙ₋₁) arranged along the first direction is connected by the intermediate line 172i to the first plasma electrode 12 arranged before it. This corresponds to a series circuit of the connecting line 171 and the respective intermediate lines 172a-172i, wherein each of these lines is characterised by a parasitic inductance L in the electrical equivalent circuit diagram (right side of FIG. 3). Therefore, the first plasma electrode 12 (E₁) arranged as first along the first direction is supplied with voltage via the first connecting line 171, the first plasma electrode 12 (E₃) arranged as second along the first direction is supplied with power via the series circuit of the first connecting line 171 and the first intermediate line 172a, the first plasma electrode 12 (E₅) arranged as third along the first direction is supplied with voltage via the series circuit of the first connecting line, the first intermediate line 172a and first intermediate line 172b, etc. In the same way, the second plasma electrodes 13 (E₂ to Eₙ) are supplied with voltage via a second connecting line 181 and a second system 180 of second intermediate lines 182a-182i, which together form the second supply network 18, from the second connection terminal B. The first feed point 173, which characterises the connection of the first connecting line 171 to the first system 170, is at the height of the first plasma electrode 12 (E₁) arranged as first along the first direction in the electrode unit 101. In the same way, the second feed point 183, which characterises the connection of the second connecting line 181 to the second system 180, lies at the height of the second plasma electrode 13 (E₂) arranged as first along the first direction in the electrode unit 101. This is called codirectional wiring or codirectional generator coupling. The high-frequency voltage is forwarded in both supply networks 17, 18 between the respective plasma electrodes 12, 13 in the same direction, here in the first direction.

As already mentioned, the connecting lines 171, 181 and the intermediate lines 172a-172i, 182a-182i can be formed as metal strips made of particularly highly conductive materials like copper or aluminium. The intermediate lines 172a-172i, 182a-182i can have a length greater than the distance between two adjacent identically connected plasma electrodes 12, 13 along the first direction, i.e. for example, greater than the distance between electrode E₁ and electrode E₃. This distance is between 6 mm and 100 mm, as also with the electrode unit according to the prior art. The length of the connecting lines 171, 181 can also be greater than the distance of the respective connection terminals A, B from the first and second plasma electrodes 12, 13 arranged as first within the electrode unit 101. By means of use of low-inductance connecting lines and intermediate lines compared to the distribution lines in the electrode unit according to the prior art, the differences in the electrode voltages through the electrode unit are greatly reduced.

This is shown in FIG. 4A and 4B. These drawings are based on measurements of the applied high-frequency voltage to identically connected plasma electrodes of an electrode unit for different frequencies of the voltage, and are consistent with simulations of the voltage curve with the usual simulation programs for electronic circuits, such as PSPICE, over a number of identically connected plasma electrodes and show the voltage deviation of the voltage applied to a specific one of these plasma electrodes in relation to the highest voltage applied to one of these plasma electrodes in each case for a frequency of 4 MHz, 13.56 MHz, or 40 MHz. FIG. 4A shows the voltage distribution for an electrode unit according to the prior art with 20 plasma electrodes, i.e. over 10 identically connected plasma electrodes, while FIG. 4B shows the voltage distribution for the first embodiment of the electrode unit according to the invention with 20 plasma electrodes. The first and second plasma electrodes of each plasma electrode pair are arranged at a distance of 15 mm from each other. The identically connected plasma electrodes, having dimensions of (200×200) mm², in each case are connected codirectionally.

As can be seen, the voltage deviation within the electrode unit according to the prior art is around 4% for a frequency of 4 MHz and therefore still tolerable. However, for higher frequencies a strongly inhomogeneous voltage distribution is present that is no longer tolerable, because it allows no homogeneous plasma treatment of the substrates through the electrode unit. By contrast, the voltage distribution for 13.56 MHz in the first embodiment of the electrode unit according to the invention is already greatly improved and can be tolerated even at 13.56 MHz.

A second embodiment 102 of the electrode unit according to the invention and the associated electrical equivalent circuit diagram are shown in FIG. 5. The electrode unit again has a first supply network 17, designed the same as the one in the first embodiment, and a second supply network 18. The second supply network 18 is formed similar to that of the first embodiment, but the second feed point 183 is now at the height of the second plasma electrode 13 arranged along the first direction (a-axis) as last in the electrode unit 102. This is the plasma electrode Eₙ. Therefore, the second intermediate line 182a, which connects the last second plasma electrode 13 (Eₙ) to the preceding second plasma electrode 13 (Eₙ₋₂), is the first intermediate line in the second system 180, while the intermediate line 182i is the last in the second system 180 and interconnects the second plasma electrodes 13 (E₂ and E₄) arranged along the first direction as the first two in the electrode unit 102.

As shown in FIG. 5, the second connection terminal B can also be arranged on the other side of electrode unit 102 with respect to the first direction. However, exactly as in the first embodiment 101, the second connection terminal B can be arranged at the lower end of the electrode unit, wherein the connecting line 181 is then correspondingly guided within in the second supply network 18 up to the last second plasma electrode 13 (Eₙ) and thus to the second feed point 183.

This arrangement of the second embodiment 102 is called reverse wiring or reverse generator coupling. The high-frequency voltage is forwarded between the respective plasma electrodes 12, 13 in the first supply network 17 along the first direction and in the second supply network 18 along a second direction opposite to the first direction. Consequently, a current that flows during the plasma treatment goes through the same number of parasitic line inductances L and parasitic capacitances between the connection terminals A and B for each plasma electrode pair, thus further increasing the homogeneity of the voltage distribution.

This can clearly be seen in FIG. 6A and 6B. FIG. 6A again shows the voltage distribution over 10 identically connected plasma electrodes of an electrode unit according to the prior art, while FIG. 6B shows the voltage distribution for the second embodiment of the electrode unit according to the invention with 10 identically connected plasma electrodes. The first and the second plasma electrode of each plasma electrode pair are again arranged at a distance of 15 mm from each other. The identically connected plasma electrodes, with dimensions of (200×200) mm², in each case are reverse-coupled to the HF voltage generator(s).

Here too a strong voltage inhomogeneity can be seen for the electrode unit according to the prior art for the frequencies 13.56 MHz and 40 MHz (FIG. 6A), while the voltage distribution for the second embodiment of the electrode unit according to the invention for the frequency of 13.56 MHz is almost homogeneous and for the frequency of 40 MHz is at least greatly improved (FIG. 6B).

FIG. 7 shows a third embodiment 103 of the electrode unit according to the invention and its electrical equivalent circuit diagram. The third embodiment 103 differs from the first and the second embodiment 101, 102 in that the first feed point 173 and the second feed point 183 are freely arranged between the first and second plasma electrodes 12, 13, respectively, arranged as first and last in the electrode unit 103 and connected to each other by the first and second systems 170, 180 of intermediate lines 172a-172i, 182a-182i. This means that connecting lines 171, 181 contact the first system 170 and the second system 180 at the height of one of the first or second plasma electrodes 12, 13 which is not the first or the last of the plasma electrodes 12, 13 within the respective system 170, 180, or one of the intermediate lines 172a-172i, 182a-182i. In the example shown in FIG. 7, the first feed point 173 lies at the height of the third first plasma electrode 12, i.e. at the height of electrode E₅, while the second feed point 183 lies at the height of the penultimate second plasma electrode 13, i.e. at the height of electrode Eₙ₋₂.

The first system 170 and the second system 180 thus each have a first part 170a, 180a and a second part 170b, 180b. The first part 170a, 180a in each case comprises the intermediate lines 172c-172i and 182i, which are arranged between the first and second plasma electrodes 12, 13 each arranged as last in the electrode unit 103, i.e. between the electrodes Eₙ₋₁ and Eₙ, and the respective feed point 173, 183. The second part 170b, 180b, by contrast, comprises the intermediate lines 172a, 172b and 182a-182h, arranged between the first and second plasma electrodes 12, 13 each arranged as first in the electrode unit 103, i.e. between the electrodes E₁ and E₂, and the respective feed point 173, 183. Therefore, the fed-in first voltage and the fed-in second voltage are forwarded in the first direction in the first part 170a of the first system 170 and in the first part 180a of the second system 180, and in a second direction opposite to the first direction in the second part 170b of the first system 170 and in the second part 180b of the second system 180.

As already mentioned with reference to FIG. 5, the connection terminals A, B need not be arranged in a particular position, especially not, as shown in FIG. 7, on a side of the electrode unit, but instead can also be arranged at the lower end or at the upper end of the electrode unit or arbitrarily arranged, wherein the connecting lines 171, 181 are then guided and configured accordingly.

The fourth embodiment 104 of the electrode unit according to the invention shown in FIG. 8 is a special case of the embodiment shown in FIG. 7, and is characterised in that the feed points 173, 183 are each arranged centrally with respect to the associated system 170, 180 of interconnected intermediate lines 172a-172d and 182a-182d. By way of example, an arrangement of ten plasma electrodes is shown. The first feed point 173 is arranged at the height of the middle first plasma electrode 12, i.e. at the height of electrode E₅, while the second feed point 183 is arranged at the height of the middle second plasma electrode 13, i.e. at the height of electrode E₆. Therefore, the first part 170a of the first system 170 and the second part 170b of the first system 170 each represent a first or second half of the first system 170, while the first part 180a of the second system 180 and the second part 180b of the second system 180 each represent a first or second half of the second system 180. A fed-in first voltage and a fed-in second voltage are therefore forwarded in the first half 170a of the first system 170 and in the first half 180a of the second system 180 in the first direction, and in the second half 170b of the first system 170 and in the second half 180b of the second system 180 in a second direction opposite to the first direction.

In the embodiments shown in FIGS. 3, 5, 7 and 8, in each case all the identically connected plasma electrodes 12, 13 are supplied with voltage by a system 170, 180 of series-connected intermediate lines 172a-172i, 182a-182i. However, this is not necessary, as will be explained later with reference to FIG. 10.

FIG. 9 shows a fifth embodiment 105 of the electrode unit according to the invention and the associated electrical equivalent circuit diagram. Here the first and the second supply network 17, 18 consist of binary-branched supply lines 174a-174g and 184a-184g having a tree-shaped arrangement. From the respective connection terminal A, B, a first supply line 174a and a second supply line 184a extend to a first or second node (branching point) 175a, 185a. From these, two other first and second supply lines 174b, 174c, 184b, 184c extend to other first and other second nodes 175b, 175c, 185b, 185c, where the supply lines branch again. This binary branching, “binary” meaning that at each node two outgoing supply lines are created from one incoming supply line, is continued until each of the first and second plasma electrodes 12, 13 is contacted by exactly one separate supply line. In FIG. 9, this is shown for four first plasma electrodes 12 and four second plasma electrodes 13. With the fifth embodiment, always 2ⁿ identically connected plasma electrodes 12, 13 can be contacted, where n is the number of node levels. In the example shown, the first plasma electrodes 12 are supplied with a first voltage via the first supply lines 174d-174g, while the second plasma electrodes 13 are supplied with a second voltage via the second supply lines 184d-184g. In the supply networks 17, 18 there are in each case two node levels, wherein a first node level contains the nodes 175a or 185a and a second node level contains the nodes 175b and 175c or 185b and 185c, respectively.

As can be learned from the associated electrical equivalent circuit diagram (right side of FIG. 9), a current that flows during the plasma treatment thus passes through the same number of line inductances L and parasitic capacitances on its way between the associated connection terminal A, B and one of the plasma electrodes 12, 13 for all the first and second identically connected plasma electrodes 12, 13. If the line conductances L and parasitic capacitances are configured similarly, which inter alia can be implemented by means of the dimensions of the metal strips or lines used as supply lines, then the voltage drop for all the plasma electrode pairs of the electrode unit is the same. A homogeneous plasma treatment for all the substrates arranged inside the electrode unit is thus achieved.

FIG. 10 shows a sixth embodiment 106 of the electrode unit according to the invention that is a hybrid of a tree-shaped and a row-shaped connection of the individual lines. The internal supply networks 17, 18 have both supply lines 174a-174e, 184a-184e and each also has a system 170, 180 of interconnected intermediate lines 172a, 172b, 182a, 182b. In the example shown, an electrode unit is shown with 10 plasma electrodes E₁-E₁₀, wherein of the first plasma electrodes 12 some (specifically electrodes E₃, E₇ and E₉) are supplied with voltage via the supply lines 174a-174e and some (specifically electrodes E₁ and E₅) via the supply lines 174a and 174b and the intermediate lines 172a, 172b. The first feed point 173 in the first system 170 is in the middle of the first system 170, but can also lie at the height of any other first plasma electrode 2 within the first system 170. The first supply lines 174a and 174b serve as connecting lines between the connection terminal A and the first feed point 173. The same configuration of the voltage feed is present in the second network 18 with which the second plasma electrodes 13 are supplied with voltage.

With such a hybrid, the voltage supply can be realized for an electrode unit with a number of first and second plasma electrodes 12, 13 which are in each case unequal to a power of 2 (≠2ⁿ), and which therefore cannot be supplied with power through a purely tree-shaped supply network of supply lines as shown in FIG. 9.

Furthermore, an internal supply network of the electrode unit according to the invention can also have multiple systems of interconnected intermediate lines, wherein the connecting lines between the associated connection terminal and the respective feed points into the systems are implemented by supply lines arranged in a tree-shaped and branched manner. Thus, in particular given a large number of plasma electrodes, the homogeneity of the voltage distribution through the identically connected plasma electrodes of the electrode unit can be further improved.

Preferably, the two internal supply networks 17 and 18, which are present in the already-described embodiments of the electrode unit according to the invention, are designed identically. In other words, the type of voltage distribution through supply lines and/or systems of interconnected intermediate lines is the same for both supply networks.

Of course, the number of plasma electrodes in the embodiments for which a concrete number is shown in FIGS. 8 to 10 is not limited to this number, but instead can be freely chosen in the context of the number realisable for the respective embodiment.

With reference to FIGS. 11 and 12, embodiments of the electrode unit according to the invention are described which each have only one internal electrical supply network 20 for feeding the voltage to the plasma electrodes 12, 13 of the electrode unit. The supply network 20 in each case is designed as a high-frequency line, wherein two systems 210, 220 of interconnected intermediate lines 212a-212i, 222a-222i are arranged spatially next to each other and not, as in the previous embodiments, spatially separated from each other. The distance between the first system 210 and the second system 220 is small enough that the two systems 210, 220 are capacitively and inductively coupled to each other. The distance is preferably in the range of 1 mm to 50 mm, and is, for example, 10 mm. The high-frequency line can be, for example, in the form of a double line of two parallel wires or two parallel metal strips, each implementing the intermediate lines 212a-212i, 222a-222i and possibly also the connecting lines 211, 221. Preferably, between the two wires or metal strips there is not only air as an insulator but a dielectric material, for example made of aluminium oxide ceramic, silicon oxide ceramic or the like, which insulates the two wires or metal strips from each other and is shown in the respective electrical equivalent circuit as capacitances C_I. The dimensions given above of the metal strips for the intermediate lines and a distance of 10 mm between the metal strips of the different systems 210, 220 as well as aluminium oxide ceramic as insulator create a double line having a typical wave impedance in the range of 10Ω to 100Ω. By means of a suitable dimensioning of the geometry of the plasma electrodes 12, 13, the load resistance of the plasma electrodes 12, 13 can also be matched, whereby the voltage feed is further homogenised. Instead of a double line, coaxial cables can also be used.

FIG. 11 shows a seventh embodiment 107 of the electrode unit according to the invention with an internal supply network 20 in which the feed points 213, 223 of both systems 210, 220 are each arranged at the height of the first and second plasma electrodes 12, 13 (E₁ and E₂) arranged as first along the first direction in the electrode unit. In other words, the feed points 213, 213 are on the same side of the electrode unit with respect to the first direction. Thus, the high-frequency line of the supply network 20 is traversed by a high-frequency current flowing during a plasma treatment to one of the systems 210, 220 and back from the other system 210, 220, i.e. the resulting current flows in the first system 210 and in the second system 220 in the opposite direction. Therefore, in each element of the two systems 210, 220, i.e. in each of the intermediate lines 212a-212i, 222a-222i, the “outflow ” is the same as the “return current,” whereby the voltage drops at the parasitic line inductances L are further reduced.

FIG. 12 shows an eighth embodiment 108 of the electrode unit according to the invention, in which, in contrast to the seventh embodiment 107, the feed points 213, 223 are on the opposite sides of the respective systems 210, 220 with respect to the first direction. Thus, for example, the first feed point 213 into the first system 210 is at the height of the first plasma electrode 12 (E₁) arranged as first along the first direction in the electrode unit, while the second feed point 223 into the second system 220 is at the height of the second plasma electrode 13 (Eₙ) arranged as last along the first direction in the electrode unit. Consequently, in the case of a plasma treatment, no high-frequency current flowing back and forth is created in the parallel lines of the systems 210, 220, but instead a high-frequency current flow is created in the same direction in both systems 210, 220. This also leads to homogenisation of the voltage distribution.

Another design of the electrode unit according to the invention is explained with respect to FIG. 13. FIG. 13 shows a ninth embodiment 109, in which the electrode unit has two supply networks 17, 18 spatially separated from each other which are configured similarly to the first embodiment shown in FIG. 3. To further reduce voltage differences possibly still present for identically connected plasma electrodes 12, 13, a dielectric layer 30 is arranged on the plasma electrodes 12, 13, in each case on the surface of plasma electrodes 12, 13 facing the plasma space 15. This acts as an additional capacitor for the respective plasma electrode pair. To homogenise the plasma generation conditions between the plasma spaces 15 of the electrode unit, the dielectric layer 30 can be matched in its properties, in particular the thickness of the layer but possibly also the material of the layer, to the respective plasma electrode pair. The dielectric layer 30 is preferably made of any of the materials like aluminium oxide, silicon oxide, zirconium oxide, or of combinations or laminations thereof, and preferably has a thickness in the range of 1 μm to 1000 μm. The thickness of the layer can be the same or different over the entire extent of the respective plasma electrodes 12, 13. For example, it may be thicker in a central area of the plasma electrodes 12, 13 than on the edges of the plasma electrodes 12, 13.

Of course, the dielectric layer can also be formed on the surface of the respective plasma electrodes 12, 13 facing the substrate 14 or on both surfaces of the plasma electrodes 12, 13. Furthermore, the dielectric layer can be arranged not on all the plasma electrodes 12, 13 but only on at least one or on selected plasma electrodes 12, 13. In addition, the supply networks 17, 18 can be designed arbitrarily according to the embodiments described above or only one electrical supply network can be present corresponding to FIGS. 11 and 12.

The high-frequency voltage generators 19a and 19b shown in FIGS. 3, 5 and 7 to 13 are each a combination of a high-frequency generator and an external matching network, as was explained with respect to FIG. 2. With the aid of the external matching networks, the returning high-frequency power to the connection terminals A, B can be set to a minimum by a suitable setting or selection of the electrical components contained. Moreover, the symmetrical voltage feed shown in all the drawings is only one preferred embodiment. An asymmetrical supply of the first and second plasma electrodes is also possible.

For all the embodiments presented thus far, the at least one internal electrical supply network can contain other passive electrical components besides the supply lines and/or intermediate lines and/or connecting lines. These can be additional inductors or capacitors that serve for further homogenisation of the voltage distribution beyond the electrode unit.

The at least one internal electrical supply network can also be designed as a printed circuit board with integrated electrical lines and integrated passive electrical components.

Some or all of the above-mentioned possibilities for improving the homogeneity of a voltage distribution with identically connected plasma electrodes of an electrode unit and the embodiments described can also be combined with each other so long as they are not mutually exclusive.

A carrier arrangement 40 according to the invention is further explained with reference to FIG. 14A to 15B. FIG. 14A and 15A each show schematic cross sections through the carrier arrangement 40 along a third direction (x-axis), i.e. along a line A′-A′, and FIG. 14B and 15B show schematic cross sections through the carrier arrangement 40 along a fourth direction (y-axis), i.e. along a line 13′-13′. The third and the fourth direction are two directions of a Cartesian coordinate system (x, y, z), which is defined with respect to the carrier arrangement 40 and is independent of the Cartesian coordinate system (a, b, c) that is defined with respect to the electrode unit and shown in FIGS. 1 to 13.

The carrier arrangement 40 in each case has at least two electrode units according to the invention arranged in a stationary manner next to each other along the third direction inside the carrier arrangement 40. Three such electrode units 10a-10c are shown schematically in FIG. 14A and 15A. Each electrode unit 10a-10c has plasma electrodes 41 and at least one internal electrical supply network, in the examples shown two supply networks 17, 18. The carrier arrangement 40 also includes a connection unit 42, which implements the electrical connection of the different electrode units 10a-10c to a high-frequency voltage generator arranged outside a treatment chamber. The connection unit 42 carries and fixes the various electrode units 10a-10c and thus ensures the mechanical stability and physical cohesion of the different electrode units 10a-10c of the carrier arrangement 40. It also ensures the electrical contact of the supply networks 17, 18 of the electrode units 10a-10c. Preferably, the carrier arrangement 40 is movable into and out of the treatment chamber of a plasma treatment system, wherein the carrier arrangement 40 is arranged in a fixed or movable manner in the treatment chamber during the plasma treatment itself. The third direction defined with reference to the carrier arrangement 40 (x-axis) is, for example, the direction along which the carrier arrangement 40 is moved into and out of the treatment chamber.

According to a first embodiment of the carrier arrangement 40 according to the invention, shown in FIG. 14A and 14B, at least one of the supply networks 17, 18 of the electrode units 10a-10c is arranged along one side of the electrode unit 10a-10c concerned that does not border another electrode unit 10a-10c. For the example shown in FIG. 14A and 14B, the supply networks 17, 18 of all the electrode units 10a-10c are arranged on both sides of the respective electrode units 10a-10c that extend along the third direction (x-axis).

According to a second embodiment of the carrier arrangement 40 according to the invention, which is shown in FIG. 15A and 15B, at least one of the supply networks 17, 18 of the electrode units 10a-10c is arranged along a side of the electrode unit 10a-10c concerned that borders another electrode unit 10a-10c. For the example shown in FIG. 15A and 15B, all the supply networks 17, 18 are arranged on both sides of the respective electrode units 10a-10c that extend along the fourth direction (y-axis), so that at least the supply networks 17, 18 of the middle electrode unit 10b are arranged between the plasma electrodes 41 of the electrode units 10a and 10b or 10b and 10c.

Preferably, the supply networks of all the electrode units of the carrier arrangement are arranged in the same manner as shown in FIG. 14A to 15B. However, at least one supply network of at least one electrode unit of the carrier arrangement can also be arranged differently if this is advantageous for the plasma treatment of the substrates or other properties of the carrier arrangement.

Furthermore, besides electrode units arranged next to each other along the third direction (x-axis) (as shown in FIG. 14A to 15B), the carrier arrangement can also contain electrode units arranged next to each other along the fourth direction (y-axis) or along a fifth direction (z-axis).

### REFERENCE SIGNS

1 electrode unit according to the prior art

2 first plasma electrode

3 second plasma electrode

4 substrate

5 plasma space

6 insulating support

7 first distribution line

8 second distribution line

9 low-frequency voltage generator 10, 10a-10c, electrode unit according to the invention

101-109

12 first plasma electrode

13 second plasma electrode

14 substrate

15 plasma space

16 insulating support

17 first supply network

18 second supply network

19a, 19b high-frequency voltage generator

20 supply network

30 dielectric layer

40 carrier arrangement

41 plasma electrode

42 connection unit

170 first system

170a first part of the first system

170b second part of the first system

171 first connecting line

172a-172i first intermediate line

173 first feed point

174a-174g first supply line

175a-175c first node

180 second system

180a first part of the second system

180b second part of the second system

181 second connecting line

182a-182i second intermediate line

183 second feed point

184a-184g second supply line

185a-185c second node

190a, 190b external matching network

210 first system

211 first connecting line

212a-212i first intermediate line

213 first feed point

220 second system

221 second connecting line

222a-222i second intermediate line

223 second feed point

A first connection terminal

B second connection terminal

1. An electrode unit, suitable for plasma treatment of a plurality of substrates in a treatment chamber of a plasma treatment system, comprising
a plurality of plasma electrode pairs along a first direction, wherein each plasma electrode pair consists of a first plasma electrode and a second plasma electrode arranged parallel to each other and opposite each other and electrically insulated from each other, and capable, in the presence of a defined voltage, of igniting a plasma in a plasma space between the first and the second plasma electrodes of the plasma electrode pair,
at least one internal electrical supply network, which is suitable, within the treatment chamber, for supplying a first voltage to each first plasma electrode of the electrode unit and a second voltage to each second plasma electrode of the electrode unit, wherein at least one of the voltages is a voltage having a frequency in the range of 1 MHz to 100 MHz,
a first connection terminal and a second connection terminal, which are suitable for feeding the first voltage through the first connection terminal and the second voltage through the second connection terminal into the at least one internal electrical supply network,
wherein the at least one internal electrical supply network is designed according to the arrangement of the plasma electrodes in the electrode unit and the frequency of the first voltage and/or the second voltage, wherein the at least one internal electrical supply network has supply lines between the first and the second connection terminal and at least two first and at least two second plasma electrodes and/or intermediate lines between two adjacent first or second plasma electrodes, and in each case one feed point into a first or second system of interconnected intermediate lines, and in each case one connecting line between the first and the second connection terminal and the associated feed point, and the design of the network consists of a suitable arrangement of the supply lines and/or suitable geometric dimensions of the supply lines and or of the intermediate lines and/or of the connecting lines and/or a suitable material of the supply lines and/or of the intermediate lines and/or of the connecting lines and/or a suitable arrangement of the feed point with respect to the electrode unit along the first direction.

2. The electrode unit according to claim 1, wherein the supply lines and/or the intermediate lines and/or the connecting lines are each metal strips having a thickness in the range from 0.1 mm to 5 mm and a width in the range from 1 mm to 100 mmm.

3. The electrode unit according to claim 1, wherein the supply lines and/or the intermediate lines and/or the connecting lines in each case are metal strips of a highly conductive material from the group comprising aluminium, copper, silver, and silver-plated copper.

4. The electrode unit according to claim 1, wherein the electrode unit has a first internal electrical supply network that is suitable, within the treatment chamber, for supplying the first voltage to each first plasma electrode of the electrode unit, and a second internal electrical supply network that is suitable, within the treatment chamber, for supplying the second voltage to each second plasma electrode of the electrode unit, wherein the first supply network and the second supply network are spatially separated from each other, the feed point of the first supply network is arranged at the height of a first plasma electrode arranged along the first direction as first in a group of first plasma electrodes connected to each other by the first system of intermediate lines, and the feed point of the second supply network is arranged at the height of a second plasma electrode arranged along the first direction as first in a group of second plasma electrodes connected to each other by the second system of intermediate lines, so that the fed-in first or second voltage is forwarded in the same direction in the first and in the second system.

5. The electrode unit according to claim 1, wherein the electrode unit has a first internal electrical supply network that is suitable, within the treatment chamber, for supplying the first voltage to each first plasma electrode of the electrode unit, and a second internal electrical supply network that is suitable, within the treatment chamber, for supplying the second voltage to each second plasma electrode of the electrode unit, wherein the first supply network and the second supply network are spatially separated from each other, the feed point of the first supply network is arranged at the height of a first plasma electrode arranged along the first direction as first in a group of first plasma electrodes connected to each other by the first system of intermediate lines, and the feed point of the second supply network is arranged at the height of a second plasma electrode arranged along the first direction as last in a group of second plasma electrodes connected to each other by the second system of intermediate lines, so that the fed-in first or second voltage is forwarded in the opposite direction in the first and in the second system.

6. The electrode unit according to claim 1, wherein the electrode unit has a first internal electrical supply network that is suitable, within the treatment chamber, for supplying the first voltage to each first plasma electrode of the electrode unit, and a second internal electrical supply network that is suitable, within the treatment chamber, for supplying the second voltage to each second plasma electrode of the electrode unit, wherein the first supply network and the second supply network are spatially separated from each other, the feed point of the first supply network is arranged between a first plasma electrode arranged along the first direction as first in a group of first plasma electrodes connected to each other by the first system of intermediate lines, and another first plasma electrode arranged along the first direction as last in the group of first plasma electrodes connected to each other by the first system of intermediate lines, and the feed point of the second supply network is arranged between a second plasma electrode arranged along the first direction as first in a group of second plasma electrodes connected to each other by the second system of intermediate lines, and another second plasma electrode arranged along the first direction as last in the group of second plasma electrodes connected to each other by the second system of intermediate lines, so that the fed-in first or second voltage is forwarded in the first direction in a first part of the first system and in a first part of the second system and in a second direction opposite to the first direction in a second part of the first system and in a second part of the second system.

7. The electrode unit according to claim 6, wherein the feed point of the first supply network is arranged along the first direction centrally in the first system of interconnected intermediate lines and the feed point of the second supply network is arranged along the first direction centrally in the second system of interconnected intermediate lines, so that the fed-in first or second voltage is forwarded in the first direction in a first half of the first system and in a first half of the second system and in a second direction that is opposite to the first direction in a second half of the first system and in a second half of the second system.

8. The electrode unit according to claim 1, wherein all first plasma electrodes of the electrode unit are supplied with voltage by the first system and all second plasma electrodes by the second system.

9. The electrode unit according to claim 1, wherein the electrode unit has a first internal electrical supply network that is suitable, within the treatment chamber, for supplying the first voltage to each first plasma electrode of the electrode unit, and a second internal electrical supply network that is suitable, within the treatment chamber, for supplying the second voltage to each second plasma electrode of the electrode unit, wherein the first supply network and the second supply network are spatially separated from each other, each supply network has supply lines between the first and the second connection terminal and at least two first and at least two second plasma electrodes and at least one supply line to at least one system of interconnected intermediate lines, wherein the supply lines, starting from a supply line that is connected to the first or second connection terminal, are divided in each case in binary fashion in a tree-shaped arrangement into two further supply lines, until each of the at least two first or at least two second plasma electrodes and the at least one system of interconnected intermediate lines are contacted by a separate supply line.

10. The electrode unit according to claim 1, wherein the electrode unit has a first internal electrical supply network that is suitable, within the treatment chamber, for supplying the first voltage to each first plasma electrode of the electrode unit, and a second internal electrical supply network that is suitable, within the treatment chamber, for supplying the second voltage to each second plasma electrode of the electrode unit, wherein the first supply network and the second supply network are spatially separated from each other, each supply network has supply lines between the first and the second connection terminal and each first and second plasma electrode, wherein the supply lines, starting from a supply line connected to the first or second connection terminal, are divided in each case in binary fashion in a tree-shaped arrangement into two further supply lines, until each first and second plasma electrode is contacted through a separate supply line.

11. The electrode unit according to claim 1, wherein the electrode unit has only one internal electrical supply network, in which the first system of interconnected intermediate lines that connects all first plasma electrodes with each other, and the second system of interconnected intermediate lines that connects all second plasma electrodes with each other, are arranged spatially next to each other at a distance small enough that a capacitive and inductive coupling between the first system and the second system is present and is not negligible, and are separated from each other by an insulator, the first system and the second system are designed as a high-frequency line, the feed point of the first system is arranged at the height of a first plasma electrode arranged along the first direction as first in a group of first plasma electrodes connected to each other by the first system, and the feed point of the second system is arranged at the height of a second plasma electrode arranged along the first direction as first in a group of second plasma electrodes connected to each other by the second system, so that during a plasma treatment a resulting current flows in opposite directions in the first system and in the second system.

12. The electrode unit according to claim 1, wherein the electrode unit has only one internal electrical supply network, in which the first system of interconnected intermediate lines that connects all first plasma electrodes with each other, and a second system of interconnected intermediate lines that connects all second plasma electrodes with each other, are arranged spatially next to each other at a distance small enough that a capacitive and inductive coupling between the first system and the second system is present and is not negligible, and are separated from each other by an insulator, the first system and the second system are designed as a high-frequency line, the feed point of the first system is arranged at the height of a first plasma electrode arranged along the first direction as first in a group of first plasma electrodes connected to each other by the first system, and the feed point of the second system is arranged at the height of a second plasma electrode arranged along the first direction as last in a group of second plasma electrodes connected to each other by the second system, so that during a plasma treatment a resulting current flows in the same direction in the first system and in the second system.

13. The electrode unit according to claim 1, wherein at least a first or at least a second plasma electrode comprises a dielectric layer on a side facing a plasma space belonging to this plasma electrode, and/or on a side facing a substrate resting on this plasma electrode.

14. The electrode unit according to claim 1, wherein the at least one internal electrical supply network contains passive electrical components in addition to the supply lines and/or the intermediate lines and/or the connecting lines.

15. The electrode unit according to claim 1, wherein the at least one internal electrical supply network is designed as a printed circuit board with integrated electrical lines and integrated passive electrical components.

16. A carrier arrangement for plasma treatment of a plurality of substrates in a treatment chamber of a plasma treatment system, wherein the carrier arrangement contains at least two electrode units according to claim 1.

17. The carrier arrangement according to claim 16, wherein at least one internal electrical supply network of one electrode unit is arranged along a side of the electrode unit that does not border another electrode unit.

18. The carrier arrangement according to claim 16, wherein at least one internal electrical supply network of one electrode unit is arranged along a side of the electrode unit that borders another electrode unit.
